(19) United States
(12) Patent Application Publication
(10) Pub. No.: US 2012/0250890 A1
(43) Pub. Date: Oct. 4, 2012

(54) AUDIO DEVICE AND METHOD FOR AUDIO OUTPUTTING

(75) Inventor: HUA-LIN LIU, Shenzhen City (CN)

(73) Assignees: HON HAI PRECISION INDUSTRY CO., LTD., Tu-Cheng (TW); FU TAI HUA INDUSTRY (SHENZHEN) CO., LTD., ShenZhen City (CN)

(21) Appl. No.: 13/205,632

(22) Filed: Aug. 9, 2011

(30) Foreign Application Priority Data
Apr. 1, 2011 (CN) 201110081592.0

(51) Int. Cl. H03G 3/00

(52) U.S. Cl. 381/107

(57) ABSTRACT

An audio device includes a headphone jack to receive a headphone plug, an audio output unit connected to the headphone jack, a detecting unit, and a control unit. The detecting unit detects insertion or removal of a headphone plug from the headphone jack. The control unit decreases an output power of the audio output unit to a preset value within a preset period in response to the detected insertion or removal of the headphone plug, and recovers the output power of the output unit to an original value after the preset period is elapsed. A related method is also provided.

### CROSS-REFERENCE TO RELATED APPLICATIONS

Related subject matter is disclosed in co-pending U.S. patents application with an Attorney Docket Number US38367 and a title of AUDIO DEVICE AND METHOD FOR AUDIO OUTPUTTING, which have the same assignees as the current application and were concurrently filed.

### BACKGROUND

1. Technical Field

The present disclosure relates to audio devices and methods for audio signals outputting of the audio devices.

2. Description of the Related Art

When a headphone is plugged in or unplugged to or from an audio device, the audio device may output an unpleasant noise.

Therefore, there is room for improvement within the art.

### BRIEF DESCRIPTION OF THE DRAWINGS

The components in the drawings are not necessarily drawn to scale, the emphasis instead being placed upon clearly illustrating the principles of an audio device and a method for muting audio signals. Moreover, in the drawings, like reference numerals designate corresponding parts throughout the several views.

FIG. 1 is a block diagram of an audio device in accordance with an exemplary embodiment.

FIG. 2 is a flowchart of a method for audio outputting of the audio device of FIG. 1 in accordance with an exemplary embodiment.

### DETAILED DESCRIPTION

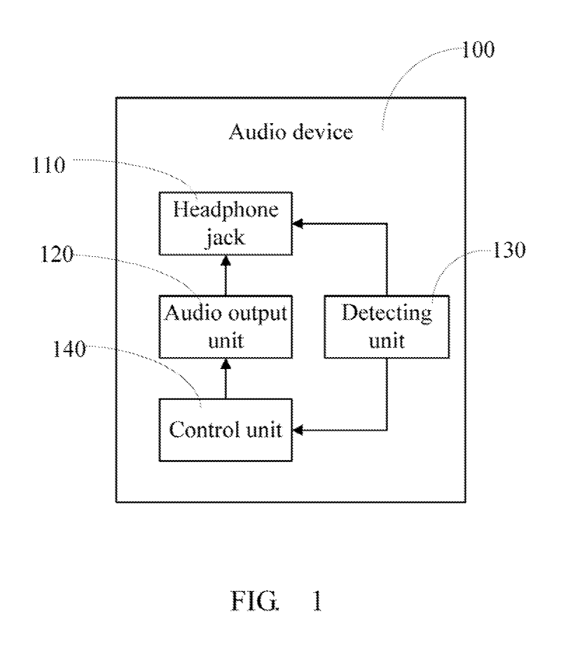

Referring to FIG. 1, an audio device 100 includes a headphone jack 110 for receiving a headphone plug, an audio output unit 120 connected to the headphone jack 110, a control unit 140 for controlling output power of the audio output unit 120, and a detecting unit 130 connected to the headphone jack 110 and the control unit 140. The detecting unit 130 is configured for detecting insertion or removal of a headphone plug from the headphone jack 110. The control unit 140 decreases an output power of the audio output unit 120 to a preset value within a preset period in response to the detected insertion or removal of the headphone plug. With such configuration, when a headphone is plugged into or pulled out of the headphone jack 110, the volume of audio signals output from the audio output unit 120 decreases, avoiding generating any unpleasant noise during the process of the plug or unplug event. The control unit 140 further recovering the output power of the output unit to an original value after the preset period is elapsed.

In the embodiment, when the detecting unit 130 detects voltage at the headphone jack 110 changes from a high level (such as 5V) to a low level (such as 1V), the detecting unit 130 determines the insertion of a headphone plug. When the detecting unit 130 detects voltage at the headphone jack 110 changes from the low level to the high level, the detecting unit 130 determines the removal of the headphone plug. The control unit 140 decreases the output power of the output unit 120 to the preset value within the preset time period when the detecting unit 130 determines that a headphone is being plugged into or pulled out of the headphone jack 110, and recovers the output power of the output unit 120 to an original value after the preset time period is elapsed. The preset value may be greater than zero or equal to zero. If the output power of the audio output unit 120 is decreased to zero, the audio output unit 120 in fact has no output and is mute.

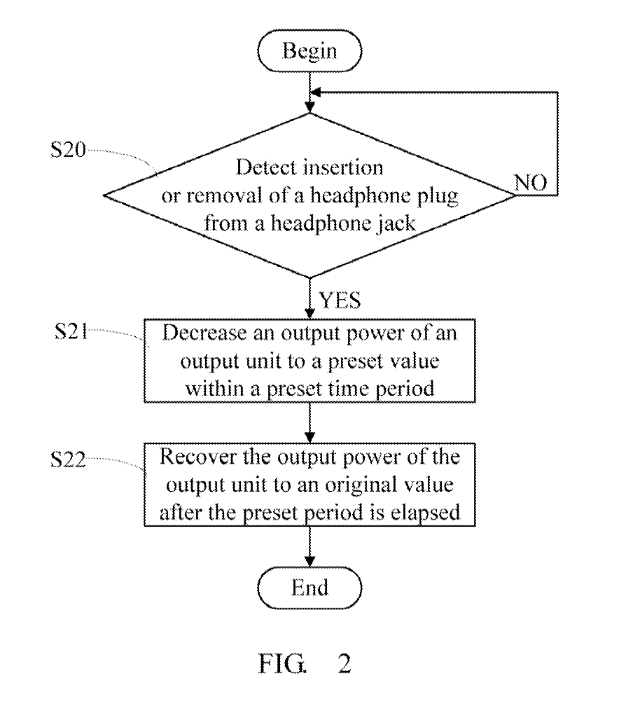

FIG. 2 is a flowchart of a method for outputting audio signal from the audio device in accordance with an exemplary embodiment.

In step S20, the detecting unit 130 detects the insertion or removal of a headphone plug from the headphone jack 110. If the detecting unit 130 detects the insertion or removal of a headphone plug from the headphone jack 110, the procedure goes to step S21, otherwise, the procedure repeats step S20.

In this embodiment, when the detecting unit 130 detects signals from the headphone jack 110 changes from a high level such as 5V to a low level such as 1V, the detecting unit 130 determines the insertion of a headphone plug. When the detecting unit 130 detects signals from the headphone jack 110 change from low level to high level, the detecting unit 130 determines the removal of a headphone plug.

In step S21, the control unit 140 decreases the output power of the output unit 120 to a preset value within the preset time period in response to detected insertion or removal of the headphone plug from the headphone jack. The preset value may be greater than zero or equal to zero.

In step S22, the control unit 140 recovers the output power of the output unit 120 to an original value after the preset period is elapsed.

It is understood that the present disclosure may be embodied in other forms without departing from the spirit thereof. Thus, the present examples and embodiments are to be considered in all respects as illustrative and not restrictive, and the disclosure is not to be limited to the details given herein.

What is claimed is:

1. An audio device comprising:
a headphone jack for receiving a headphone plug;
an audio output unit connected to the headphone jack;
a detecting unit for detecting insertion or removal of a headphone plug from the headphone jack; and
a control unit for decreasing an output power of the audio output unit to a preset value within a preset period in response to the detected insertion or removal of the headphone plug, and recovering the output power of the output unit to an original value after the preset period is elapsed.

2. The audio device as recited in claim 1, wherein the preset value is greater than zero.

3. The audio device as recited in claim 1, wherein the preset value is equal to zero.

4. The audio device as recited in claim 1, wherein the detecting unit is configured to determine the insertion of a plug by detecting a voltage at the headphone jack changes from a high level to a low level, and the detecting unit is configured to determine the removal of a plug by detecting the voltage at the headphone jack changes from a low level to a high level.

5. A method for outputting audio signals from an audio device, the audio device comprising a headphone jack, the method comprising:
detecting insertion or removal of a headphone plug from the headphone jack;
decreasing an output power of an audio output unit of the audio device to a preset value within a preset period in response to detected insertion or removal of the headphone from the headphone jack; and
recovering the output power of the audio output unit to an original value after the preset period is elapsed.

6. The method as recited in claim 5, wherein the preset value is greater than zero.

7. The method as recited in claim 5, wherein the preset value is equal to zero.

8. The method as recited in claim 5, wherein the insertion of the headphone plug is determined by detecting a voltage at the headphone jack changes from a high level to a low level.

9. The method as recited in claim 5, wherein the removal of the headphone plug is determined by detecting a voltage at the headphone jack changes from a low level to a high level.
